(19) United States
(12) Patent Application Publication
(10) Pub. No.: US 2013/0306471 A1
(43) Pub. Date: Nov. 21, 2013

(54) SPUTTERING TARGET FOR FORMING MAGNETIC RECORDING MEDIUM FILM AND METHOD FOR PRODUCING SAME

(71) Applicants: Kouichi Ishiyama, Naka-shi (JP); Sohei Nonaka, Sanda-shi (JP); Masanori Yosuke, Sanda-shi (JP); Hideharu Matsuzaki, Sanda-shi (JP)

(72) Inventors: Kouichi Ishiyama, Naka-shi (JP); Sohei Nonaka, Sanda-shi (JP); Masanori Yosuke, Sanda-shi (JP); Hideharu Matsuzaki, Sanda-shi (JP)

(21) Appl. No.: 13/982,443

(22) PCT Filed: Jan. 27, 2012
(86) PCT No.: PCT/JP2012/000520

§ 371 Date: Jul. 29, 2013

(30) Foreign Application Priority Data
Jan. 31, 2011 (JP) 2011-019178
Jan. 25, 2012 (JP) 2012-012629

(51) Int. Cl. C23C 14/34

(52) U.S. Cl. CPC C23C 14/3414
USPC 204/298.13; 264/109

(57) ABSTRACT

Provided are a sputtering target for forming a magnetic recording medium film, on which a film having a low ordering temperature can be formed and which can suppress generation of particles, and a method for producing the same. The sputtering target for forming a magnetic recording medium film consists of a sintered body having a composition represented by the general formula: {(FeₓPt₁₀₀₋ₓ)_{(100-y)}Ag_{y}}_{(100-z)}C_{z}, wherein x, y, and z are represented by atomic percent as 30≦x≦80, 1≦y≦30, and 3≦z≦63. Also, the method for producing the sputtering target has a step of hot pressing a mixed powder of AgPt alloy powder, FePt alloy powder, Pt powder, and graphite powder or carbon black powder in a vacuum or an inert gas atmosphere.

### BACKGROUND OF THE INVENTION

1. Field of the Invention

The present invention relates to a magnetic recording film which is applied to a high-density magnetic recording medium for hard disk drives, and particularly relates to a sputtering target for forming a magnetic recording film which is applied to a perpendicular magnetic recording medium or a heat-assisted magnetic recording medium and a method for producing the same.

2. Description of the Related Art

In general, hard disk drives have been used as external recording devices for computers, digital home electric appliances, and the like, and a further improvement in recording density has been demanded. Thus, in recent years, a perpendicular magnetic recording method that can realize high-density recording has been employed. Unlike an earlier in-plane recording method, in the perpendicular magnetic recording method, recorded magnetization is theoretically stabilized as the recording density is increased.

Furthermore, there has been proposed a heat-assisted magnetic recording method as an extra high-density magnetic recording method of the next generation, where the heat-assisted magnetic recording method is a combination of the perpendicular magnetic recording techniques, the optical recording techniques, and the like. The heat-assisted magnetic recording method is a recording method that performs writing in a recording film composed of a ferromagnetic material having a high coercive force by a magnetic field in a state where the coercive force of the recording film is reduced by applying heat with the laser beam or microwave. As a candidate of materials to be applied to the recording layer of the hard disk medium in the heat-assisted magnetic recording method, there has been proposed a C (carbon)-containing FePt-based magnetic recording film (see Non-Patent Document 1). Conventionally, in order to form a C-containing FePt-based magnetic recording film (hereinafter referred to as “FePt—C film”), a FePt sputtering target and a C sputtering target are prepared. Then, FePt and C are subject to co-sputtering using these sputtering targets to thereby produce a FePt—C film.

Since a FePt film formed by the sputtering method is a disordered phase in the metastable state, the FePt film needs to be subject to heat treatment to a temperature (ordering temperature) of phase transition to the ordered phase of the L1₀ structure having high crystalline magnetic anisotropy. However, this heat treatment is inappropriate for mass production because this ordering temperature is high, and thus, there has been a demand for a sputtered film having a low ordering temperature. Thus, it has been conventionally investigated to lower the ordering temperature by using a FePtAg film in which Ag is added to a FePt film or a FePtCu film in which Cu is added to the same (see Non-Patent Document 2).

### PRIOR ART DOCUMENTS

### Non-Patent Documents

[Non-Patent Document 1] Yingfan Xu, M. L. Yan, and D. J. Sellmyer, Nanostructure and Magnetic Properties of FePt: C Cluster Films, IEEE TRANSACTIONS ON MAGNETICS, VOL 40, No. 4, JULY 2004, p. 2525-2527
[Non-Patent Document 2] Tomoyuki Maeda and 4 others, The reduction in ordering temperature of a FePt ordered alloy by the addition of Cu, JOURNAL OF THE MAGNETICS SOCIETY OF JAPAN, VOL 26, No. 4, 2002, p. 426-429
[Non-Patent Document 3] Tetsu Kikitsu and 6 others, The influence of residual oxygen in FePt thin film on ordering temperature, Technical Research Report of Electronic Information Communication Association MR 2003-31 (2003-11) p. 25

### SUMMARY OF THE INVENTION

### Problems to be Solved by the Invention

However, the following problems still remain in the conventional techniques described above.

Specifically, since a FePt sputtering target and a C sputtering target have been conventionally subject to co-sputtering in order to obtain a FePt—C film, two types of sputtering targets need to be prepared and C powder particles are generated from the C sputtering target, resulting in the abnormal electrical discharge. In addition, since a FePt alloy target and an Ag target have also been conventionally subject to co-sputtering to form a FePtAg film, two types of sputtering targets need to be prepared as in the FePt—C film.

The present invention has been made in view of the aforementioned circumstances, and an object of the present invention is to provide a sputtering target for forming a magnetic recording medium film, on which a FePtAg—C film having a low ordering temperature can be formed and which can suppress generation of particles, and a method for producing the same.

### Means for Solving the Problems

The present invention adopts the following structure in order to solve the aforementioned problems. Specifically, a sputtering target for forming a magnetic recording medium film according to a first aspect of the present invention is characterized in that the sputtering target consists of a sintered body having a composition represented by the general formula: {(FeₓPt₁₀₀₋ₓ)_{(100-y)}Ag_{y}}_{(100-z)}C_{z}, wherein x, y, and z are represented by atomic percent as 30≦x≦80, 1≦y≦30, and 3≦z≦63.

Since the sputtering target for forming a magnetic recording medium film consists of a sintered body having a composition represented by the general formula: {(FeₓPt₁₀₀₋ₓ)_{(100-y)}Ag_{y}}_{(100-z)}C_{z}, wherein x, y, and z are represented by atomic percent as 30≦x≦80, 1≦y≦30, and 3≦z≦63, a FePtAg—C film having a low ordering temperature by the presence of Ag can be formed by using a single target and C particles are hardly generated by the incorporation of C into a metal matrix consisting of Fe, Pt, and Ag, resulting in suppression of occurrence of abnormal electrical discharge during sputtering.

The reason why Fe is set in the above composition range is as follows. If Fe is less than 30 at % or greater than 80 at %, such composition falls largely outside the region of FePt ordered phase (L1₀ structure) designated by the Fe—Pt binary phase equilibrium diagram, and thus, a FePt ordered phase is not sufficiently formed on a magnetic recording layer after film formation.

Also, the reason why Ag is set in the above composition range is as follows. If Ag is less than 1 at %, a significant effect of lowering the ordering temperature of a magnetic recording film cannot be obtained by the addition of Ag. If Ag is greater than 30 at %, the target with sufficiently high density cannot be obtained, resulting in ready occurrence of particles.

Furthermore, the reason why C is set in the above composition range is as follows. If C is less than 3 at %, high recording density cannot be realized because of the insufficiently fine structure of the magnetic recording film. If C is greater than 63 at %, the target with sufficiently high density cannot be obtained, resulting in ready occurrence of particles.

Also, a sputtering target for forming a magnetic recording medium film according to a second aspect of the present invention is characterized in that, when a part of the Ag is substituted with at least one of Au and Cu and the substituted metal is given as M, the sputtering target consists of a sintered body having a composition represented by the general formula: {(FeₓPt₁₀₀₋ₓ)_{(100-y)}(Ag₁₀₀₋ₐMₐ)_{y}}_{(100-z)}C_{z}, wherein x, y, and z are represented by atomic percent as 30≦x≦80, 1≦y≦30, 3≦z≦63, and 0<a≦50.

Since the sputtering target for forming a magnetic recording medium film consists of a sintered body having a composition represented by the general formula: {(FeₓPt₁₀₀₋ₓ)_{(100-y)}(Ag₁₀₀₋ₐMₐ)_{y}}_{(100-z)}C_{z} when a part of the Ag is substituted with at least one of Au and Cu and the substituted metal is given as M, wherein x, y, and z are represented by atomic percent as 30≦x≦80, 1≦y≦30, 3≦z≦63, and 0<a≦50, a FePtAgM-C film having a low ordering temperature by the presence of Ag and at least one of Au and Cu can be formed by using a single target and C particles are hardly generated by the incorporation of C into a metal matrix consisting of Fe, Pt, Ag, and M, resulting in suppression of occurrence of abnormal electrical discharge during sputtering.

In the sputtering target for forming a magnetic recording medium film, 50 at % or less of Ag is substituted with at least one of Au and Cu(M). The reason why M is set in the above composition range is as follows. Although Au and Cu have the same ordering temperature lowering effect as that of Ag, a hot-pressing temperature needs to be set to higher than the case of Ag alone. Additionally, if the substituted one of Au and Cu(M) is greater than 50 at %, the target with sufficiently high density cannot be obtained, resulting in ready occurrence of particles.

A sputtering target for forming a magnetic recording medium film according to a third aspect of the present invention is characterized in that the content of oxygen is equal to or less than 500 ppm in the first or the second aspect of the present invention.

Specifically, in the sputtering target for forming a magnetic recording medium film, the ordering temperature of the magnetic recording medium film formed by sputtering can be readily lowered, resulting in obtaining a high coercive force even when a heat treatment temperature is low.

The reason why the content of oxygen is equal to or less than 500 ppm is because, if the content of oxygen is greater than 500 ppm, the effect of lowering the ordering temperature of the magnetic recording medium film consisting of Ag, Au, and Cu is reduced.

Note that the influence of residual oxygen in a FePt thin film on the ordering temperature is also described in Non-Patent Document 3. Non-Patent Document 3 discloses the fact that, when the amount of oxygen in the target is 3000 ppm, the amount of oxygen in the sputtered magnetic recording medium film is in the range of from 700 to 1000 ppm and the coercive force Hc (when heat-treated at 300° C.) thereof is about 5 kOe, whereas when the amount of oxygen in the target is 50 ppm, the amount of oxygen in the sputtered magnetic recording medium film is in the range of from 100 to 200 ppm and the coercive force Hc (when heat-treated at 300° C.) thereof is improved to about 8 kOe.

A method for producing a sputtering target for forming a magnetic recording medium film according to a fourth aspect of the present invention is a method for producing the sputtering target for forming a magnetic recording medium film according to the first aspect of the present invention and is characterized in that the method includes a step of hot pressing a mixed powder of AgPt alloy powder, FePt alloy powder, Pt powder, and graphite powder or carbon black powder in a vacuum or an inert gas atmosphere.

A method for producing a sputtering target for forming a magnetic recording medium film according to a fifth aspect of the present invention is a method for producing the sputtering target for forming a magnetic recording medium film according to the second aspect of the present invention and is characterized in that the method includes a step of hot pressing a mixed powder of AgPt alloy powder, at least one of AuPt alloy powder and CuPt alloy powder, FePt alloy powder, Pt powder, and graphite powder or carbon black powder in a vacuum or an inert gas atmosphere.

When pure Ag powder is used as raw material for the addition of Ag, Ag with a low melting point first starts melting. Thus, a sintering temperature during hot-pressing must be set to low, resulting in a reduction in density of the target. In contrast, in the method for producing a sputtering target for forming a magnetic recording medium film of the present invention, a mixed powder of AgPt alloy powder, FePt alloy powder, Pt powder, and graphite powder or carbon black powder is hot pressed in a vacuum or an inert gas atmosphere. Thus, a sintering temperature during hot-pressing can be increased by mixing AgPt alloy powder having a higher melting point than that of pure Ag, resulting in obtaining a high-density target.

When pure Au powder or pure Cu powder is used as raw material for the addition of Au or Cu, Au or Cu with a low melting point first starts melting. Thus, a sintering temperature during hot-pressing must be set to low, resulting in a reduction in density of the target. In contrast, in the method for producing a sputtering target for forming a magnetic recording medium film of the present invention, a mixed powder of AgPt alloy powder, at least one of AuPt alloy powder and CuPt alloy powder, FePt alloy powder, Pt powder, and graphite powder or carbon black powder is hot pressed in a vacuum or an inert gas atmosphere. Thus, a sintering temperature during hot-pressing can be increased by mixing at least one of AuPt alloy powder and CuPt alloy powder having a higher melting point than that of pure Au powder or pure Cu powder, resulting in obtaining a high-density target.

A method for producing a sputtering target for forming a magnetic recording medium film according to a sixth aspect of the present invention is characterized in that the carbon black powder is generated by thermal decomposition of acetylene gas in the fourth or fifth aspect of the present invention.

Specifically, in the method for producing the sputtering target for forming a magnetic recording medium film, carbon black powder is so-called acetylene black which is generated by thermal decomposition of acetylene gas. Thus, fine acetylene black (fine C powder) is distributed into a metal matrix consisting of one or more of Fe, Pt, Ag, and M in a highly distributed state and the target having a high-density structure can be obtained.

A method for producing a sputtering target for forming a magnetic recording medium film according to a seventh aspect of the present invention is characterized in that the graphite powder or the carbon black powder in the mixed powder is heat-treated in advance in a vacuum in any one of the fourth to sixth aspects of the present invention.

Specifically, in the method for producing the sputtering target for forming a magnetic recording medium film, graphite powder or carbon black powder in the mixed powder is heat-treated in advance in a vacuum. Thus, a relatively large amount of a gaseous component such as oxygen contained in graphite powder or carbon black powder is removed in advance so that the amount of oxygen or the like contained as inevitable impurities in a sintered body can be readily reduced.

### Effects of the Invention

According to the present invention, the following effects may be provided.

Specifically, since the sputtering target for forming a magnetic recording medium film of the present invention consists of a sintered body having a composition represented by the general formula: {(FeₓPt₁₀₀₋ₓ)_{(100-y)}Ag_{y}}_{(100-z)}C_{z}, wherein x, y, and z are represented by atomic percent as 30≦x≦80, 1≦y≦30, and 3≦z≦63, a FePtAg—C film having a low ordering temperature by the presence of Ag can be formed by using a single target and C particles are hardly generated by the incorporation of C into a metal matrix consisting of Fe, Pt, and Ag, resulting in suppression of occurrence of abnormal electrical discharge during sputtering.

Thus, the sputtering target for forming a magnetic recording medium film of the present invention is used to form a magnetic recording medium film form by sputtering so that a magnetic recording film having a low ordering temperature, which is applied to a high-density magnetic recording medium for hard disk drives can be obtained with high productivity. In particular, a favorable magnetic recording film which is applied to a perpendicular magnetic recording medium or a heat-assisted magnetic recording medium can be obtained.

### BRIEF DESCRIPTION OF THE DRAWINGS

FIG. 1 is a diagram illustrating a flow of manufacturing a sputtering target for forming a magnetic recording medium film and a method for producing the same according to one embodiment of the present invention.

### BEST MODES FOR CARRYING OUT THE INVENTION

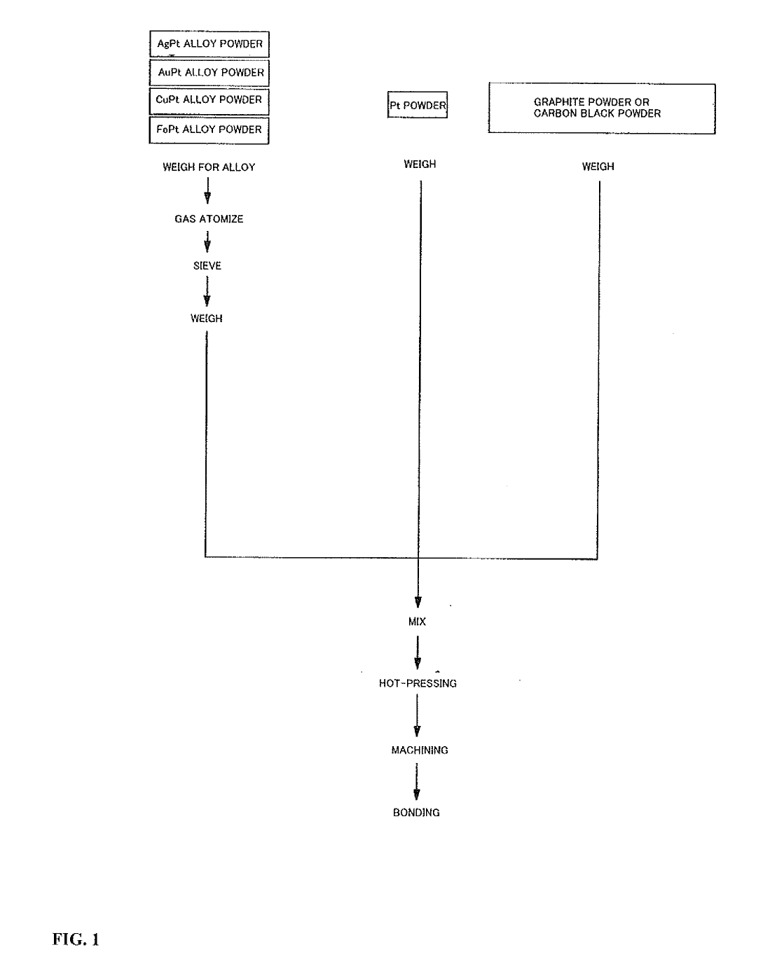

Hereinafter, a description will be given of a sputtering target for forming a magnetic recording medium film and a method for producing the same according to one embodiment of the present invention with reference to FIG. 1.

The sputtering target for forming a magnetic recording medium film of the present embodiment consists of a sintered body having a composition represented by the general formula: {(FeₓPt₁₀₀₋ₓ)_{(100-y)}Ag_{y}}_{(100-z})C_{z}, wherein x, y, and z are represented by atomic percent as 30≦x≦80, 1≦y≦30, and 3≦z≦63.

When a part of the Ag is substituted with at least one of Au and Cu and the substituted metal is given as M, the sputtering target may also consist of a sintered body having a composition represented by the general formula: {(FeₓPt₁₀₀₋ₓ)_{(100-y)}(Ag₁₀₀₋ₐMₐ)_{y}}_{(100-z)}C_{z}, wherein x, y, and z are represented by atomic percent as 30≦x≦80, 1≦y≦30, 3≦z≦63, and 0<a≦50.

The sintered body has a structure in which C is incorporated into an alloy metal matrix consisting of one or more of Fe, Pt, Ag, and M (at least one of Au and Cu).

In the sputtering target for forming a magnetic recording medium film, it is preferable that the content of oxygen (O) is equal to or less than 500 ppm.

Furthermore, it is preferable that the content of nitrogen (N) is equal to or less than 150 ppm. The reason why it is preferable that the content of nitrogen (N) is equal to or less than 150 ppm is because, if the content of nitrogen (N) is greater than 150 ppm, a soft magnetic Fe₄N phase is generated in the magnetic recording medium film, resulting in possible reduction in a coercive force (Hc).

As shown in FIG. 1, the method for producing a sputtering target for forming a magnetic recording medium film includes a step of hot pressing a mixed powder of AgPt alloy powder, AuPt alloy powder, CuPt alloy powder, FePt alloy powder, Pt powder, and graphite powder or carbon black powder in a vacuum or an inert gas atmosphere.

In particular, as carbon black powder, it is preferable that so-called acetylene black which is generated by thermal decomposition of acetylene gas is used.

It is preferable that the above AgPt alloy powder is AgPt alloy powder containing 5 to 95 at % of Ag. It is preferable that the above AuPt alloy powder is AuPt alloy powder containing 10 to 90 at % of Au. It is preferable that the above CuPt alloy powder is CuPt alloy powder containing 10 to 90 at % of Cu. It is preferable that the above FePt alloy powder is FePt alloy powder containing 80 to 95 at % of Fe. It is preferable that the above Pt powder has an average particle diameter of 1 to 5 μm. Furthermore, it is preferable that graphite powder or carbon black powder has an average particle diameter of 0.02 to 20 μm.

It is preferable that graphite powder or carbon black powder is heat-treated in advance in a vacuum.

Furthermore, it is preferable that FePt alloy powder having a particle diameter of 5 μm or less is removed. The reason why it is preferable that FePt alloy powder having a particle diameter of 5 μm or less is removed is because a gas component such as oxygen, nitrogen, and the like contained in FePt alloy powder can be further reduced by removing fine powder of large surface area having a particle diameter of 5 μm or less.

It is preferable that AgPt alloy powder, AuPt alloy powder, CuPt alloy powder, and FePt alloy powder have an average particle diameter of from 10 to 30 μm. The reason why the average particle diameter of these alloy powders is set in the above range is as follows. If the average particle diameter is less than 10 μm, it becomes difficult to efficiently recover these alloy powders, whereas if the average particle diameter exceeds 30 μm, the target with sufficiently high density cannot be obtained, resulting in ready occurrence of particles.

A detailed description will be given for an example of the manufacturing method. For example, firstly, AgPt alloy powder, AuPt alloy powder, CuPt alloy powder, and FePt alloy powder were produced by gas atomization so as to obtain a predetermined composition in percentage as described above, and then were sieved to obtain the average particle diameter of from 10 to 30 μm. Then, the resulting powder was recovered.

As Pt powder, a commercially available one may be used. For example Pt powder with purity of from 3N to 4N having an average particle diameter of from 1 to 5 μm may be prepared.

As carbon black powder, so-called acetylene black which is generated by self-exothermic decomposition of acetylene gas by periodically repeating combustion and thermal decomposition of acetylene gas as raw material is used. For example, carbon black powder having an average particle diameter of 35 nm and a specific surface area (BET value) of 70 m²/g is used.

Note that carbon black powder is subject to heat treatment in advance in a vacuum of from 1×10⁻³ to 1×10⁻⁵ Torr (133×10⁻³ to 133×10⁻⁵ Pa) at a heat treatment temperature of from 1100° C. to 1300° C. for 1 to 4 hours for degassing.

Next, AgPt alloy powder, AuPt alloy powder, CuPt alloy powder, FePt alloy powder, Pt powder, and graphite powder or carbon black powder are weighed so as to obtain a predetermined target composition as described above. These powders are charged into a pot for ball milling and mixing together with 5 mm diameter zirconia balls serving as a grinding medium for mixing or the like. Then, the lid is closed after air in a pot is substituted with Ar gas. Furthermore, the pot is rotated for 2 to 16 hours so that the raw materials are mixed to obtain a mixed powder.

Next, the resulting mixed powder is formed and sintered by hot-pressing in a vacuum and the resulting sintered body is machined so as to reach a predetermined target dimension. In order to obtain a sintered body with sufficiently high density, the resulting mixed powder needs to be subject to hot-pressing at a pressurizing force of 200 kgf/cm² or greater but is restricted by the mechanical strength of a mold and the maximum load for a pressing device. Thus, it is preferable that hot-pressing is performed at a temperature of from 950° C. to 1300° C. for holding hours of from 3 to 12 hours at a pressurizing force of 350 kgf/cm².

Thus obtained sintered body and a backing plate are bonded together to form a target.

As described above, since the sputtering target for forming a magnetic recording medium film of the present embodiment consists of a sintered body having a composition represented by the general formula: {(FeₓPt₁₀₀₋ₓ)_{(100-y)}Ag_{y}}_{(100-z)}C_{z}, wherein x, y, and z are represented by atomic percent as 30 x≦80, 1≦y≦30, and 3≦z≦63, a FePtAg—C film having a low ordering temperature by the presence of Ag can be formed by using a single target and C particles are hardly generated by the incorporation of C into a metal matrix consisting of Fe, Pt, and Ag, resulting in suppression of occurrence of abnormal electrical discharge during sputtering.

Since the sputtering target for forming a magnetic recording medium film of the present embodiment consists of a sintered body having a composition represented by the general formula: {(FeₓPt₁₀₀₋ₓ)_{(100-y)}(Ag₁₀₀₋ₐMₐ)_{y}}_{(100-z)}C_{z} when a part of the Ag is substituted with at least one of Au and Cu and the substituted metal is given as M, wherein x, y, and z are represented by atomic percent as 30≦x≦80, 1≦y≦30, 3≦z≦63, and 0<a≦50, a FePtAgM-C film having a low ordering temperature by the presence of Ag and M can be formed by using a single target and C particles are hardly generated by the incorporation of C into a metal matrix consisting of one or more of Fe, Pt, Ag, and M, resulting in suppression of occurrence of abnormal electrical discharge during sputtering.

Furthermore, since the content of oxygen is equal to or less than 500 ppm in the sputtering target for forming a magnetic recording medium film, the ordering temperature of the magnetic recording medium film formed by sputtering can be readily lowered, resulting in obtaining a high coercive force even when a heat treatment temperature is low. By setting the content of nitrogen to be equal to or less than 150 ppm, a soft magnetic Fe₄N phase is not generated in the magnetic recording medium film and a high coercive force can be obtained.

In the method for producing a sputtering target for forming a magnetic recording medium film of the present invention, a mixed powder of AgPt alloy powder, AuPt alloy powder, CuPt alloy powder, FePt alloy powder, Pt powder, and graphite powder or carbon black powder is hot pressed in a vacuum or an inert gas atmosphere. Thus, a sintering temperature during hot-pressing can be increased by mixing AgPt alloy powder having a higher melting point than that of pure Ag, resulting in obtaining a high-density target.

In particular, carbon black powder is so-called acetylene black which is generated by thermal decomposition of acetylene gas. Thus, fine acetylene black (fine C powder) is distributed into a metal matrix consisting of one or more of Fe, Pt, Ag, and M in a highly distributed state and the target having a high-density structure can be obtained.

Graphite powder or carbon black powder in the mixed powder is heat-treated in advance in a vacuum. Thus, a relatively large amount of a gaseous component such as oxygen contained in graphite powder or carbon black powder is removed in advance so that the amount of oxygen or the like contained as inevitable impurities in a sintered body can be readily reduced.

### EXAMPLES

Next, a description will be given of the evaluation results of the actually produced sputtering targets for forming a magnetic recording medium film of the present invention in Examples based on the above embodiment with reference to FIG. 1.

Firstly, FIG. 1 is a diagram illustrating a flow of manufacturing a sputtering target for forming a magnetic recording medium film of the present invention.

For AgPt alloy atomized powder, an Ag pellet with purity 4N and sponge-like Pt with purity 3N were used as raw materials and were dissolved in a gas atomization apparatus such that the concentration of Ag reaches 55 at %. Then, the resulting powder was gas atomized by the use of Ar gas to create AgPt alloy atomized powder for recovery. The recovered powder was sieved to thereby obtain AgPt alloy atomized powder having an average particle diameter of 12 μm.

For AuPt alloy atomized powder, an Au pellet with purity 4N and sponge-like Pt with purity 3N were used as raw materials and were dissolved in a gas atomization apparatus such that the concentration of Au reaches 80 at %. Then, the resulting powder was gas atomized by the use of Ar gas to create AuPt alloy atomized powder for recovery. The recovered powder was sieved to thereby obtain AuPt alloy atomized powder having an average particle diameter of 12 μm.

For CuPt alloy atomized powder, a Cu block with purity 4N and sponge-like Pt with purity 3N were used as raw materials and were dissolved in a gas atomization apparatus such that the concentration of Cu reaches 75 at %. Then, the resulting powder was gas atomized by the use of Ar gas to create CuPt alloy atomized powder for recovery. The recovered powder was sieved to thereby obtain CuPt alloy atomized powder having an average particle diameter of 12 μm.

For FePt alloy atomized powder, electrolytic iron with purity 3N and sponge-like Pt with purity 3N were used as raw materials and were dissolved in a gas atomization apparatus such that the concentration of Fe reaches 93 at %. Then, the resulting powder was gas atomized by the use of Ar gas to create FePt alloy atomized powder for recovery. The recovered powder was sieved to thereby obtain FePt alloy atomized powder having an average particle diameter of 16 μm.

Next, a description will be given of a sintering method using hot-pressing.

In accordance with the manufacturing flow shown in FIG. 1, AgPt alloy atomized powder, AuPt alloy atomized powder, CuPt alloy atomized powder, FePt alloy atomized powder, Pt powder with purity 3N having an average particle diameter of 3 μm, and acetylene black powder as carbon black powder with purity 3N having an average particle diameter of 0.035 μm, which have been sieved, were weighed so as to obtain a predetermined target composition. Next, these weighed powders were charged into a pot for ball milling and mixing together with 5 mm diameter zirconia balls serving as a grinding medium for mixing or the like. Then, the lid was closed after air in a pot was substituted with Ar gas. Furthermore, the pot was rotated for 2 to 16 hours so that the raw materials were mixed to obtain a mixed powder. The resulting mixed powder was charged into a hot-pressing device with the mixed powder being filled into a graphite mold and was sintered in a vacuum atmosphere at a reached vacuum pressure of 1×10⁻³ Torr (133×10⁻³ Pa) under the conditions of pressurizing force: 350 kgf/cm², holding temperature: 1150° C., and holding hours: 6 hours to thereby obtain a sintered body of the target of the present invention.

Then, each sintered body was machined to thereby create a target for analysis having a diameter of 50 mm and a thickness of 2 mm and a target for sputtering having a diameter of 152 mm and a thickness of 6 mm. Furthermore, the target for sputtering was bonded to a backing plate made of oxygen-free copper by In soldering to thereby form a sputtering target. The density of the target for analysis was measured by Archimedes method to thereby calculate a density ratio. The density ratio was calculated by dividing the bulk density of the sintered body by the theoretical density thereof. Note that the theoretical density was calculated by the following formula.

$${ρ}_{fn} = \frac{1}{( \begin{matrix}\frac{{C}_{Fe} / 100}{{ρ}_{Fe}} + \frac{{C}_{Pt} / 100}{{ρ}_{Pt}} + \frac{{C}_{Ag} / 100}{{ρ}_{Ag}} + \\ \frac{{C}_{Au} / 100}{{ρ}_{Au}} + \frac{{C}_{Cu} / 100}{{ρ}_{Cu}} + \frac{{C}_{C} / 100}{{ρ}_{C}}\end{matrix} )} \\ UNIT \text{:} g \text{/} cm 3 \qquad [ Formula 1 ]$$

ρ_{Fe}: DENSITY OF Fe, C_{Fe}: % BY WEIGHT OF Fe
ρ_{Pt}: DENSITY OF Pt, C_{Pt}: % BY WEIGHT OF Pt
ρ_{Ag}: DENSITY OF Ag, C_{Ag}: % BY WEIGHT OF Ag
ρ_{Au}: DENSITY OF Au, C_{Au}: % BY WEIGHT OF Au
ρ_{Cu}: DENSITY OF Cu, C_{Cu}% BY WEIGHT OF Cu
ρ_{C}: DENSITY OF C, C_{C}: % BY WEIGHT OF C
ρ_{fn}: THEORETICAL DENSITY

Next, the target in this Example was installed on a DC magnetron sputtering apparatus. The DC magnetron sputtering apparatus was subject to vacuum evacuation (reached vacuum pressure: 1×10⁻⁶ Torr (133×10⁻⁶ Pa)) and then Ar gas was introduced into the apparatus so that the pressure (sputtering gas pressure) in the apparatus reached 5×10⁻³ Torr (665×10⁻³ Pa). After the target was subject to pre-sputtering using a DC power source with a sputtering power of 500 W for 30 mins, the target was then subject to continuous sputtering using a DC power source with a sputtering power of 800 W for 5 hours. The number of times abnormal electrical discharge occurred in the target was measured by a measurement device with attached power source. Then, a FePtAg(M)-C film with a thickness of 50 nm was deposited on a single-crystal MgO substrate. The film was subject to heat treatment in a reducing atmosphere at a temperature of from 250° C. to 600° C. for 15 min, where a temperature at which the coercive force (Hc) of the film was increased to be 3 kOe or greater was determined as the crystallization temperature. The coercive force (Hc) was determined by measuring a B-H curve in a direction perpendicular to the film surface using a vibrating sample magnetometer (maximum applied magnetic field: 15 kOe). The size of magnetic particles contained in the ordered film was observed by a transmission electron microscope to thereby measure an average particle diameter. The average particle diameter (unit: nm) was calculated by the following formula.

Average particle diameter=200/√(Nπ)

(N is the number of magnetic particles contained in an observation region which has a square shape having one side of 100 nm)

TABLE 1

| | | | a | | | DENSITY | ORDERING | AVERAGE |
|---|---|---|---|---|---|---|---|---|
| | x | y | (AMOUNT | | z | RATIO OF | TEMPERATURE | PARTICLE |
| | (AMOUNT | (AMOUNT | OF M) | | (AMOUNT | TARGET | OF FILM | DIAMETER AFTER |
| | OF Fe) | OF Ag + M) | Au | Cu | OF C) | (%) | (° C.) | ORDERING (nm) |
| EXAMPLE 1 | 55.4 | 10.2 | 0.0 | 0.0 | 35.2 | 97.5 | 350 | 7.5 |
| EXAMPLE 2 | 54.2 | 9.8 | 27.7 | 21.2 | 4.1 | 98.4 | 350 | 12.8 |
| EXAMPLE 3 | 64.6 | 21.3 | 5.4 | 13.9 | 59.2 | 93.2 | 330 | 4.9 |
| EXAMPLE 4 | 50.7 | 16.5 | 0.0 | 46.8 | 42.5 | 87.1 | 340 | 6.2 |
| EXAMPLE 5 | 69.2 | 1.2 | 0.0 | 0.0 | 43.3 | 97.8 | 400 | 6.4 |
| EXAMPLE 6 | 47.8 | 1.1 | 32.9 | 0.0 | 25.8 | 98.7 | 410 | 7.0 |
| EXAMPLE 7 | 57.3 | 29.7 | 0.0 | 0.0 | 13.6 | 96.3 | 320 | 7.6 |
| EXAMPLE 8 | 56.1 | 28.9 | 0.0 | 45.8 | 52.7 | 88.2 | 330 | 5.8 |
| EXAMPLE 9 | 45.7 | 17.3 | 0.0 | 0.0 | 3.0 | 97.8 | 330 | 10.3 |
| EXAMPLE 10 | 65.5 | 5.6 | 0.0 | 0.0 | 62.1 | 86.9 | 370 | 4.4 |
| COMPARATIVE | 55.6 | 0.7 | 0.0 | 0.0 | 33.0 | 99.9 | 550 | 7.1 |
| EXAMPLE 1 | | | | | | | | |
| COMPARATIVE | 58.7 | 0.8 | 24.9 | 0.0 | 9.8 | 99.7 | 530 | 9.9 |
| EXAMPLE 2 | | | | | | | | |
| COMPARATIVE | 55.9 | 31.1 | 0.0 | 0.0 | 33.0 | 83.3 | 320 | 6.8 |
| EXAMPLE 3 | | | | | | | | |
| COMPARATIVE | 54.5 | 30.7 | 5.5 | 9.9 | 17.8 | 84.0 | 320 | 8.1 |
| EXAMPLE 4 | | | | | | | | |
| COMPARATIVE | 51.2 | 27.0 | 17.2 | 35.9 | 39.5 | 81.8 | 330 | 6.5 |
| EXAMPLE 5 | | | | | | | | |
| COMPARATIVE | 55.1 | 25.9 | 0.0 | 52.7 | 40.2 | 81.1 | 330 | 6.5 |
| EXAMPLE 6 | | | | | | | | |
| COMPARATIVE | 52.8 | 14.4 | 0.0 | 0.0 | 2.0 | 90.6 | 350 | >50 |
| EXAMPLE 7 | | | | | | | | |
| COMPARATIVE | 53.6 | 13.8 | 0.0 | 15.1 | 64.0 | 80.7 | 360 | 4.2 |
| EXAMPLE 8 | | | | | | | | |

For the targets having a density ratio of 85% or greater shown in Examples, abnormal electrical discharge due to the presence of particles did not occur during the continuous sputtering. In addition, for the films created by using the targets shown in Examples, the films not only have a ordering temperature decreased to 450° C. or lower but also have a fine structure including magnetic particles having an average particle diameter of 15 nm or less. Thus, it can be seen that these films are suitable for realizing high recording density.

Next, the amount of oxygen contained in the produced targets was examined for two cases: with or without heat treatment for graphite powder and carbon black powder. In these Examples, as shown in Table 2, the amount of oxygen contained in the targets was examined for two cases: with or without heat treatment for two types of powders, i.e., graphite powder and acetylene black.

In Examples, the targets are produced by the same conditions other than the presence or absence of the above heat treatment. In addition, the targets have the same composition and are produced by the same manufacturing conditions.

The amount of oxygen was measured by an infrared absorption method described in JIS Z 2613, “Generalization in quantitative method of determining oxygen in metal material”. The results are shown in Table 2.

TABLE 2

| | AMOUNT OF |
|---|---|
| RAW MATERIAL C USED | OXYGEN (PPM) IN TARGET |
| GRAPHITE POWDER | 560 |
| (WITHOUT HEAT TREATMENT) | |
| GRAPHITE POWDER | 260 |
| (WITH HEAT TREATMENT) | |
| ACETYLENE BLACK | 480 |
| (WITHOUT HEAT TREATMENT) | |
| ACETYLENE BLACK | 210 |
| (WITH HEAT TREATMENT) | |

As can be seen from these results, the amount of oxygen in the targets were significantly reduced with heat treatment for both graphite powder and acetylene black. In particular, when acetylene black is used, the amount of oxygen in the target is reduced more than the case of using graphite powder.

As described above, if a sputtering target in which the amount of oxygen is significantly reduced is used, a high coercive force can be obtained in a low heat treatment temperature of about 300° C. as described in Non-Patent Document 3.

In order to utilize the present invention as a sputtering target, it is preferable that the relative density is 80% or greater, the surface roughness (Ra) is 12.5 μm or less, the particle diameter is 100 μm or less, the electrical resistance is 10 Ω·cm or less, the metal-type impurity concentration is 0.1 at % or less, and the flexural strength is 10 MPa or greater. These conditions are satisfied in the above Examples.

The technical scope of the present invention is not limited to the aforementioned embodiments and Examples, but the present invention may be modified in various ways without departing from the scope or teaching of the present invention.

What is claimed is:

1. A sputtering target for forming a magnetic recording medium film comprising:
a sintered body having a composition represented by the general formula: {(FeₓPt₁₀₀₋ₓ)_{(100-y)}Ag_{y}}_{(100-z)}C_{z}, wherein x, y, and z are represented by atomic percent as 30≦x≦80, 1≦y≦30, and 3≦z≦63.

2. The sputtering target for forming a magnetic recording medium film according to claim 1, wherein, when a part of the Ag is substituted with at least one of Au and Cu and the substituted metal is given as M, the sputtering target consists of a sintered body having a composition represented by the general formula: {(FeₓPt₁₀₀₋ₓ)_{(100-y)}(Ag₁₀₀₋ₐMₐ)_{y}}_{(100-z)}C_{z}, wherein x, y, and z are represented by atomic percent as 30≦x≦<80, 1≦y≦30, 3≦z≦63, and 0<a≦50.

3. The sputtering target for forming a magnetic recording medium film according to claim 1, wherein the content of oxygen is equal to or less than 500 ppm.

4. A method for producing the sputtering target for forming a magnetic recording medium film according to claim 1, the method comprising:
a step of hot pressing a mixed powder of AgPt alloy powder, FePt alloy powder, Pt powder, and graphite powder or carbon black powder in a vacuum or an inert gas atmosphere.

5. A method for producing the sputtering target for forming a magnetic recording medium film according to claim 2, the method comprising:
a step of hot pressing a mixed powder of AgPt alloy powder, at least one of AuPt alloy powder and CuPt alloy powder, FePt alloy powder, Pt powder, and graphite powder or carbon black powder in a vacuum or an inert gas atmosphere.

6. The method for producing a sputtering target for forming a magnetic recording medium film according to claim 4, wherein the carbon black powder is generated by self-exothermic decomposition of acetylene gas.

7. The method for producing a sputtering target for forming a magnetic recording medium film according to claim 4, wherein the graphite powder or the carbon black powder in the mixed powder is heat-treated in advance in a vacuum.
